(19) United States
(12) Patent Application Publication
(10) Pub. No.: US 2025/0220962 A1
(43) Pub. Date: Jul. 3, 2025

(54) THIN FILM TRANSISTOR, MANUFACTURING METHOD THEREOF, AND DISPLAY APPARATUS COMPRISING THE SAME

(71) Applicant: LG Display Co., Ltd., Seoul (KR)

(72) Inventor: Yongjae KIM, Paju-si (KR)

(21) Appl. No.: 18/898,232

(22) Filed: Sep. 26, 2024

(30) Foreign Application Priority Data
Dec. 29, 2023 (KR) 10-2023-0197345

(51) Int. Cl. H01L 29/417; H01L 29/423; H01L 29/66; H01L 29/786; H10K 59/121

(52) U.S. Cl. CPC H10D 30/6729; H10D 30/031; H10D 30/6723; H10D 30/673; H10K 59/1213

(57) ABSTRACT

A thin film transistor, a method of manufacturing the same, and a display apparatus including the same are disclosed. The thin film transistor includes an active layer, a gate electrode spaced apart from the active layer and overlapping at least part of the active layer, a source electrode, and a drain electrode spaced apart from the source electrode and connected to the active layer. Each of the gate, source, and drain electrodes include a first layer and a second layer on the first layer. Each of the source, drain electrodes is connected to the active layer through a first contact portion, the first contact portion contacts the second layer of the source electrode and the second layer of the drain electrode, respectively, the first layer includes a metal oxide containing an element M, the second layer includes a low resistance metal, and the element includes a group 6B element.

### CROSS-REFERENCE TO RELATED APPLICATIONS

This application claims the benefit of priority of the Korean Patent Application No. 10-2023-0197345 filed on Dec. 29, 2023, which is hereby incorporated by reference as if fully set forth herein.

### BACKGROUND

### Technical Field

The present disclosure relates to a thin film transistor, a method of manufacturing the same, and a display apparatus including the same.

### Description of the Related Art

Transistors are widely used as switching devices or driving devices in the electronic device field. In particular, since a thin film transistor may be manufactured on a glass substrate or a plastic substrate, it is widely used as a switching device of a display apparatus such as a liquid crystal display apparatus or an organic light emitting device.

### BRIEF SUMMARY

The inventors of the present disclosure have continuously researched methods of implementing transistors that have low reflection. In particular, an embodiment of the present disclosure is to provide a thin film transistor in which the source electrode and the drain electrode have low reflection characteristics to suppress or prevent an increase in reflectance.

An embodiment of the present disclosure is to provide a thin film transistor having low resistance wiring characteristics while suppressing or preventing an increase in reflectance by adjusting a double layer structure having low reflection characteristics of a source electrode and a drain electrode.

Another embodiment of the present disclosure is to provide a display apparatus including such a thin film transistor.

Another embodiment of the present disclosure is to provide a method of manufacturing such a thin film transistor.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor including a base substrate; an active layer on the base substrate; a gate electrode spaced apart from the active layer and overlapping at least part of the active layer from a plan view; a source electrode connected to the active layer and a drain electrode spaced apart from the source electrode and connected to the active layer; each of the gate electrode, the source electrode and the drain electrode includes a first layer and a second layer on the first layer; each of the source electrode and the drain electrode is connected to the active layer through a first contact portion; each of the first contact portion contacts the second layer of the source electrode and the second layer of the drain electrode; the first layer includes a metal oxide (MOx) containing an element M; the second layer includes a low resistance metal; and the element includes a group 6B element.

The group 6B element may include at least one of chromium (Cr), molybdenum (Mo), and tungsten (W), and the low resistance metal may include at least one of Cu, Ag, Al, Mo, and Ti.

The first layer may further include a dopant, and the dopant may include at least one of Ta, Ti, and Zn.

The first layer of the source electrode, the first layer of the drain electrode, and the first layer of the gate electrode may be formed on the same layer.

The gate electrode, the source electrode, and the drain electrode may be formed on the same layer.

The active layer may include a channel area overlapping the gate electrode (e.g., when seen from a plan view), a source area connected to one side of the channel area, and a drain area connected to the other side of the channel area, and the first contact portion may be disposed on the source area and the drain area.

The first contact portion can include at least one selected from metal and transparent conductive oxide (TCO).

The metal may include a molybdenum-titanium alloy (MoTi).

Each of the first layer of the source electrode, the first layer of the drain electrode, and the first layer of the gate electrode may have a thickness of 200 to 600 Å.

A light blocking layer on the base substrate may be further included, and the source electrode may be connected to the light blocking layer through a second contact portion.

The light blocking layer may include a first layer and a second layer on the first layer, the first layer may include a metal oxide (MOx) containing an element M, the second layer may include a low resistance metal, the element M may include a group 6B element, and the low resistance metal may include at least one of Cu, Ag, Al, Mo, and Ti.

The second contact portion may include a low resistance metal, and the low resistance metal may include at least one of Cu, Ag, Al, Mo, and Ti.

The second contact portion may include a first layer in contact with the light blocking layer and a second layer on the first layer, the first layer may include molybdenum-titanium alloy (MoTi), and the second layer may include the low resistance metal.

At least a part of the first layer of the second contact portion may contact any one of the first layer of the source electrode and the first layer of the drain electrode, and the first contact portion may contact the first layer of the source electrode and the first layer of the drain electrode.

Another configuration of the present disclosure provides a display apparatus including the thin film transistor.

Another embodiment of the present disclosure provides a manufacturing method of the thin film transistor including forming an active layer on the base substrate, forming a first contact portion on the active layer, forming a low-reflective material layer on the active layer, forming a first metal material layer on the low-reflective material layer, forming a gate electrode, a source electrode, and a drain electrode by etching the low-reflective material layer and the first metal material layer. Each of the gate electrode, the source electrode, and the drain electrode includes a first layer and a second layer on the first layer, and each of the source electrode and the drain electrode is connected to the active layer through a first contact portion, and the first contact portion contacts each of the second layer of the source electrode and the second layer of the drain electrode, and the first layer includes a metal oxide (MOx) containing an element M, the second layer includes a low resistance metal, and the element M includes a group 6B element.

The step of forming the first contact portion on the active layer may be performed by sequentially forming the oxide semiconductor material layer and the second metal material layer, and then patterning using a halftone mask.

The step of forming the first contact portion on the active layer is performed after the step of forming a low-reflective material layer on the active layer, and the step of forming a first photoresist material layer on the low-reflective material layer to etch part of it, forming a second metal material layer on the first photoresist material layer; and removing the first photoresist material layer and the second metal material layer formed on the first photoresist material layer may be further included.

The step of forming the first contact portion on the active layer is performed after the step of forming a low-reflective material layer on the active layer, and the step of forming a first photoresist material layer on the low-reflective material layer, and etching using a mask; the step of removing the first photoresist material layer; the step of forming a second metal material layer on the low-reflective material layer; the step of forming a second photoresist material layer on the second metal material layer; and the step of removing the second metal material layer that does not overlap the second photoresist material layer using the mask may be included.

One of the first photoresist material layer and the second photoresist material layer may be formed of a positive type photoresist pattern, and the other may be formed of a negative type photoresist pattern.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a cross-sectional view of a thin film transistor according to an embodiment of the present disclosure.

FIG. 2 is a cross-sectional view of a thin film transistor according to another embodiment of the present disclosure.

FIG. 3 is a cross-sectional view of a thin film transistor according to another embodiment of the present disclosure.

FIG. 4 is a cross-sectional view of a thin film transistor according to another embodiment of the present disclosure.

FIG. 5 is a cross-sectional view of a thin film transistor according to another embodiment of the present disclosure.

FIG. 6 is a diagram showing a mechanism for reflection of external light.

FIGS. 7A to 7D are process diagrams showing a process of manufacturing a thin film transistor according to an embodiment of the present disclosure.

FIGS. 8A to 8G are process diagrams showing a process of manufacturing a thin film transistor according to another embodiment of the present disclosure.

FIGS. 9A to 9G are process diagrams showing a process of manufacturing a thin film transistor according to another embodiment of the present disclosure.

FIG. 10 is a schematic view of a display apparatus according to an embodiment of the present disclosure.

FIG. 11 is a circuit diagram of any one pixel of FIG. 10.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a dimension (e.g., length, width, height, thickness, radius, diameter, area, etc.), a ratio, an angle, and a number of elements disclosed in the drawings for describing embodiments of the present disclosure are merely an example and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

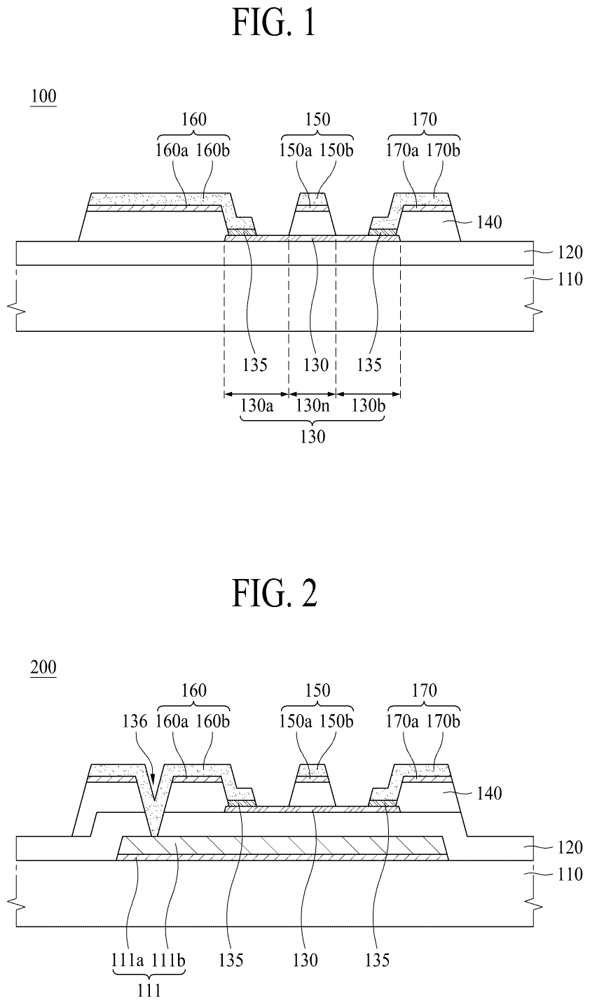

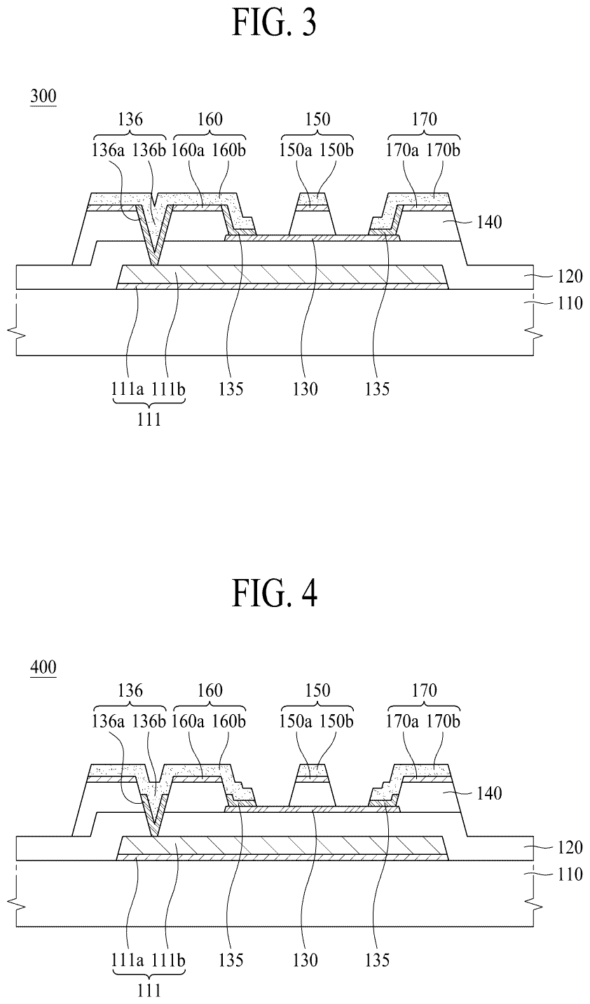

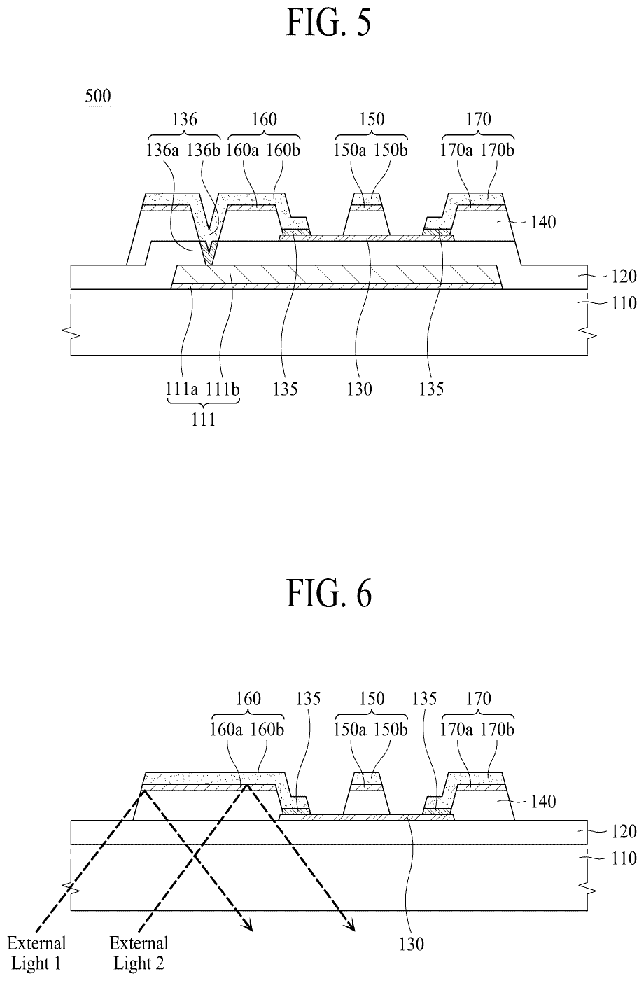

FIG. 1 is a cross-sectional view of a thin film transistor 100 according to an embodiment of the present disclosure. FIG. 2 is a cross-sectional view of a thin film transistor 200 according to another embodiment of the present disclosure. FIG. 3 is a cross-sectional view of a thin film transistor 300 according to another embodiment of the present disclosure. FIG. 4 is a cross-sectional view of a thin film transistor 400 according to another embodiment of the present disclosure. FIG. 5 is a cross-sectional view of a thin film transistor 500 according to another embodiment of the present disclosure.

Specifically, referring to FIG. 1, the buffer layer 120 on the base substrate 110, the active layer 130 on the buffer layer 120, the gate electrode 150 spaced apart from the active layer 130 to at least partially overlap the active layer 130, the source electrode 160 and the drain electrode 170 connected to the active layer 130 are disposed.

According to an embodiment of the present disclosure, the thin film transistor 100 may further include a base substrate 110. Referring to FIG. 1, the buffer layer 120 is disposed on the base substrate 110.

According to an embodiment of the present disclosure, the thin film transistor 100 may further include a gate insulating layer 140. Referring to FIG. 1, the gate insulating layer 140 is disposed on the active layer 130. Specifically, the gate insulating layer 140 is disposed between the active layer 130 and the gate electrode 150.

According to an embodiment of the present disclosure, another layer of the thin film transistor 100 may be additionally disposed on the gate electrode 150. In detail, the thin film transistor 100 may further include an interlayer insulating layer. Although not shown in the drawings, the gate electrode 150 may be disposed between the gate insulating layer 140 and the interlayer insulating layer.

Hereinafter, components of the thin film transistor 100 according to an embodiment of the present disclosure will be described in more detail.

Glass or plastic may be used for the base substrate 110. Transparent plastic having flexible characteristics, for example, polyimide, may be used as plastic.

When the polyimide is used as the base substrate 110, considering that a high-temperature deposition process is performed on the base substrate 110, a heat-resistant polyimide capable of withstanding a high temperature may be used. In this case, in order to form a thin film transistor, processes such as deposition, etching, and the like may be performed in a state in which the polyimide substrate is disposed on the carrier substrate made of a high-durable material such as glass.

Referring to FIG. 1, a buffer layer 120 may be disposed on the base substrate 110.

The buffer layer 120 is formed on the base substrate 110 and may be formed of an inorganic material or an organic material. For example, an insulating oxide such as silicon oxide (SiOx), silicon nitride (SiNx), silicon oxynitride (SiON), aluminum oxide (Al₂O₃).

The buffer layer 120 protects the active layer 130 by blocking impurities such as moisture and oxygen introduced from the base substrate 110, serves to flatten the upper portion of the base substrate 110, and may be formed as a single layer or a plurality of layers.

Referring to FIGS. 1 and 2, an active layer 130 may be disposed on the buffer layer 120.

The active layer 130 may include a channel area 130n, a source area 130a, and a drain area 130b.

The channel area 130n overlaps the gate electrode 150. The channel area 130n serves as a channel of the thin film transistor 100.

Specifically, the active layer 130 may include a channel area 130n overlapping the gate electrode 150, a source area 130a connected to one side of the channel area 130n, and a drain area 130b connected to the other side of the channel area 130n without overlapping the gate electrode 150.

According to an embodiment of the present disclosure, the source area 130a and the drain area 130b are spaced apart from each other with the channel area 130n interposed therebetween.

According to an configuration of the present disclosure, the active layer 130 may be formed of a semiconductor material. The active layer 130 may include an oxide semiconductor material.

The oxide semiconductor material may include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, an embodiment of the present disclosure is not limited thereto, and the active layer 130 may be made of another oxide semiconductor material known in the art.

The source area 130a and the drain area 130b may be formed by selective conductorization with respect to the active layer 130 made of a semiconductor material. According to an embodiment of the present disclosure, imparting conductivity to a specific portion of the active layer 130 so that it may function as a conductor is referred to as selective conductorization. By this selective conductorization, a portion to which conductivity is imparted is conductorized, and a portion to which conductivity is not imparted is not conductorized.

Although a configuration in which the active layer 130 is formed of a single layer is disclosed in FIG. 1, an configuration of the present disclosure is not limited thereto. The active layer 130 may have a single layer structure or a multilayer structure.

According to an embodiment of the present disclosure, the channel area 130n, the source area 130a, and the drain area 130b of the active layer 130 may be integrally formed, and the active layer 130 may have a constant thickness. Specifically, the active layer 130 may have substantially the same thickness.

The gate insulating layer 140 is disposed on the active layer 130. The gate insulating layer 140 protects the channel area 130n. Specifically, the gate insulating layer 140 is disposed between the active layer 130 and the gate electrode 150.

The gate insulating layer 140 has insulating properties. The gate insulating layer 140 may include at least one of silicon oxide, silicon nitride, and metal-based oxide, for example. The gate insulating layer 140 may have a single layer structure or a multilayer structure.

The gate electrode 150 is disposed on the gate insulating layer 140. The gate electrode 150 overlaps the channel area 130n of the active layer 130.

According to an embodiment of the present disclosure, the gate electrode 150 may include a first layer 150a and a second layer 150b on the first layer 150a.

Specifically, the first layer 150a of the gate electrode 150 may include a metal oxide (MOx) containing an element M, and the second layer 150b may include a low resistance metal. In this case, the element M may include a group 6B element.

For example, the element of group 6B may include at least one of chromium (Cr), molybdenum (Mo), and tungsten (W).

For example, the low-resistance metal may include at least one of Cu, Ag, Al, Mo, and Ti.

When the first layer 150a of the gate electrode 150 includes a metal oxide (MOx) containing an element M and the second layer 150b includes a low resistance metal, the first layer 150a may reflect a part of light incident from the outside, and transmit or absorb the remaining part of the light. Also, the remaining light that has passed through transmission or absorption in the first layer 150a may be reflected from the surface of the second layer 150b of the gate electrode 150. Accordingly, the light reflected from the first layer 150a and the second layer 150b meet on the surface of the first layer 150a in a state of being in opposite phases to cause destructive interference. As a result, an increase in reflectance due to external light in the display apparatus may be reduced or prevented.

According to an embodiment of the present disclosure, the first layer 150a of the gate electrode 150 may further include a dopant. Specifically, the first layer 150a of the gate electrode 150 may further include a dopant to improve optical characteristics. In this case, the dopant may include at least one of Ta, Ti, and Zn.

However, an embodiment of the present disclosure is not limited thereto, and the first layers 160a and 170a of the source electrode 160 and the drain electrode 170 may further include a dopant.

According to an embodiment of the present disclosure, the gate insulating layer 140 may be patterned by etching using the gate electrode 150 as a mask, and in this process, the active layer 130 may be selectively conductorized to form the source area 130a and the drain area 130b. Specifically, according to an embodiment of the present disclosure, a region of the active layer 130 overlapping the gate electrode 150 is not conductorized to become a channel area 130n having semiconductor characteristics, and a region that does not overlap the gate electrode 150 may be conductorized to become the source area 130a and the drain area 130b.

According to an embodiment of the present disclosure, the thin film transistor 100 may include a source electrode 160 and a drain electrode 170. Positions of the source electrode 160 and the drain electrode 170 may be exchanged with each other. However, an embodiment of the present disclosure is not limited thereto, and the source area 130a and the drain area 130b may serve as source electrodes and drain electrodes, respectively.

Referring to FIG. 1, each of the source electrode 160 and the drain electrode 170 may be connected to the active layer 130 through a contact hole. Specifically, the source electrode 160 may be in contact with the source area 130a through a contact hole. The drain electrode 170 may be spaced apart from the source electrode 160 to be in contact with the drain area 130b through a contact hole. More specifically, the source electrode 160 and the drain electrode 170 may be connected to the active layer 130 through the first contact portion 135.

Hereinafter, the source electrode 160, the drain electrode 170, and the first contact portion 135 according to an embodiment of the present disclosure will be described in detail.

Referring to FIG. 1, the source electrode 160 is connected to the active layer 130, and the drain electrode 170 is spaced apart from the source electrode 160, and is connected to the active layer 130.

The source electrode 160 and the drain electrode 170 include first layers 160a and 170a and second layers 160b and 170b on the first layers 160a and 170a, respectively.

In this case, the first layers 150a, 160a, and 170a of the gate electrode 150, the source electrode 160, and the drain electrode 170 may be disposed on the same layer. Specifically, referring to FIG. 1, the first layers 150a, 160a, and 170a of the gate electrode 150, the source electrode 160, and the drain electrode 170 are disposed on the gate insulating layer 140. More specifically, the first layers 150a, 160a, and 170a of the gate electrode 150, the source electrode 160, and the drain electrode 170 may be formed of the same material by the same process.

According to an embodiment of the present disclosure, the gate electrode 150, the source electrode 160, and the drain electrode 170 may be disposed on the same layer. Specifically, referring to FIG. 1, the gate electrode 150, the source electrode 160, and the drain electrode 170 are disposed on the gate insulating layer 140. More specifically, the gate electrode 150, the source electrode 160, and the drain electrode 170 may be formed of the same material by the same process.

According to an embodiment of the present disclosure, the first layers 160a and 170a of the source electrode 160 and the drain electrode 170 may include a metal oxide (MOx) containing an element M, and the second layers 160b and 170b may include a low resistance metal. In this case, the element M may include a group 6B element.

For example, the element of group 6B may include at least one of chromium (Cr), molybdenum (Mo), and tungsten (W).

For example, the low resistance metal may include at least one of Cu, Ag, Al, Mo, and Ti.

When the first layers 160a and 170a of the source electrode 160 and the drain electrode 170 include a metal oxide (MOx) containing an element M and the second layers 160b and 170b include a low resistance metal, the first layers 160a and 170a may reflect a part of light incident from the outside, and transmit or absorb the remaining part of the light. Furthermore, the remaining light transmitted or absorbed from the first layers 160a and 170a may be reflected from the surfaces of the second layers 160b and 170b of the source electrode 160 and the drain electrode 170. Accordingly, the light reflected from the first layers 160a and 170b meets on the surfaces of the first layers 160a and 170a in a state of being opposite phases to each other, causing destructive interference. As a result, an increase in reflectance due to external light in the display apparatus may be reduced or prevented.

In addition, when the second layers 160b and 170b of the source electrode 160 and the drain electrode 170 contain a low-resistance metal material (a low-resistance metal material) such as a low-resistance metal, the source electrode 160 and the drain electrode 170 can serve as a wiring with low-resistance characteristics.

That is, in the source electrode 160 and the drain electrode 170 according to the present disclosure, the first layers 160a and 170a include metal oxide (MOx) containing the element M, thereby reducing the reflectance of light incident from the outside. At the same time, the second layers 160b and 170b contain a low-resistance metal, thereby lowering the resistance of the source electrode 160 and the drain electrode 170, so that they may serve as wiring.

According to an embodiment of the present disclosure, the first contact portion 135 may be in contact with the second layer 160b of the source electrode 160 and the second layer 170b of the drain electrode 170, respectively.

Specifically, the first contact portion 135 may be disposed on the source area 130a and the drain area 130b of the active layer 130. In FIG. 1, a structure in which the second layer 160b of the source electrode 160 is connected to the source area 130a through the first contact portion 135 is illustrated, and a structure in which the second layer 170b of the drain electrode 170 is connected to the drain area 130b through the first contact portion 135 is illustrated.

According to an embodiment of the present disclosure, the first contact portion may include at least one selected from a metal and a transparent conductive oxide (TCO). Specifically, the metal may include molybdenum-titanium alloy (MoTi), and the transparent conductive oxide (TCO) may include ITO (InSnO), IZO (InZnO), IO (InO), TO (SnO), and ZO (ZnO). However, an embodiment of the present disclosure is not limited thereto, and the first contact portion 135 may include an oxide having conductivity.

The first contact portion 135 may have reducibility. The active layer 130 may be selectively conductorized by the first contact portion 135. According to an embodiment of the present disclosure, the source area 130a and the drain area 130b contact the first contact portion 135, respectively. A region of the active layer 130, which is in contact with the first contact portion 135, is conductorized, and a source area 130a and a drain area 130b may be formed, respectively.

Specifically, according to an embodiment of the present disclosure, portions of the active layer 130 in contact with the first contact portion 135 may be reduced, respectively, to form a source area 130a and a drain area 130b.

For example, when a portion of the active layer 130 contacting and overlapping the first contact portion 135 is reduced, an oxygen vacuum occurs in the active layer 130, and accordingly, the active layer 130 may be selectively conductorized. By the selective reduction of the active layer 130, the source area 130a and the drain area 130b may be formed.

According to an embodiment of the present disclosure, a separate layer including a metal or a conductive oxide is not provided between the first layers 150a, 160a, and 170a of the gate electrode 150, the source electrode 160, and the drain electrode 170 and the gate insulating layer 140.

When a separate layer including a metal or conductive oxide having high reflectivity is disposed between the gate insulating layer 140 and the first layers 150a, 160a, and 170a of the gate electrode 150, the source electrode 160, and the drain electrode 170, the reflectance with respect to light incident from the outside is excessively increased. As a result, it may be difficult to suppress an increase in reflectance with respect to external light in the display apparatus.

According to an embodiment of the present disclosure, the first layers 150a, 160a, and 170a of the gate electrode 150, the source electrode 160, and the drain electrode 170 may each have a thickness of 200 to 600 Å. In this case, when the first layers 150a, 160a, and 170a of the gate electrode 150, the source electrode 160, and the drain electrode 170 have a thickness of 200 to 600 Å, the first layers 150a, 160a, and 170a may be efficiently stacked on the gate insulating layer 140 and at the same time have excellent low reflection characteristics.

On the other hand, when the first layers 150a, 160a, and 170a of the gate electrode 150, the source electrode 160, and the drain electrode 170 have a thickness of less than 200 Å, the first layers 150a, 160a, and 170a are not sufficiently stacked, and thus the thin film transistor 100 may not have excellent low reflection characteristics.

In addition, when the first layers 150a, 160a, and 170a of the gate electrode 150, the source electrode 160, and the drain electrode 170 have a thickness greater than 600 Å, the distance between the gate electrode 150 and the active layer 130 may become excessively distant, resulting in a problem in that the influence of the electric field generated in the gate electrode 150 is excessively reduced. In addition, when the first layers 150a, 160a, and 170a have a thickness greater than 600 Å, the thickness of the first layers 150a, 160a, and 170a may become excessively thick, resulting in a step difference between each layer, resulting in a problem in that a seam occurs in the step difference.

The thin film transistor 200 according to an embodiment of the present disclosure may further include a light blocking layer 111. FIG. 2 shows a structure in which the light blocking layer 111 is disposed on the base substrate 110.

According to an embodiment of the present disclosure, the source electrode 160 may be connected to the light blocking layer 111 through the second contact portion 136. FIG. 2 shows a structure in which the source electrode 160 and the light blocking layer 111 are connected through the second contact portion 136.

According to an embodiment of the present disclosure, the light blocking layer 111 may include a first layer 111a and a second layer 111b on the first layer 111a. In detail, the first layer 111a of the light blocking layer 111 may include a metal oxide (MOx) containing an element M, and the second layer 111b may include a low resistance metal. In this case, the element M may include a group 6B element. For example, the group 6B element may include at least one of chromium (Cr), molybdenum (Mo), and tungsten (W), and the low resistance metal may include at least one of Cu, Ag, Al, Mo, and Ti.

FIG. 2 further includes a light blocking layer 111 compared to FIG. 1, and even in this case, the first layer 111a of the light blocking layer 111 may reflect a part of light incident from the outside, and transmit or absorb the remaining part of the light. Also, the remaining light that has passed through transmission or absorption in the first layer 111a may be reflected on the surface of the second layer 111b of the light blocking layer 111. Accordingly, the light reflected from the first layer 111a and the second layer 111b meet on the surface of the first layer 111a in a state of being opposite phases to each other, causing destructive interference. As a result, an increase in reflectance due to external light in the display apparatus may be reduced or prevented.

According to an embodiment of the present disclosure, the second contact portion 136 may include a low resistance metal. Specifically, the second contact portion 136 may be formed of the same material as those of the second layers 150b, 160b, and 170b of the gate electrode 150, the source electrode 160, and the drain electrode 170.

According to an embodiment of the present disclosure, the second contact portion 136 may include a first layer 136a and a second layer 136b on the first layer 136a. Specifically, referring to FIG. 3, the second contact portion 136 may include a first layer 136a which is in contact with the light blocking layer 111 and a second layer 136b which is in contact with the source electrode 160.

The second contact portion 136 refers to an area formed inside the hole as compared to the source electrode 160. Specifically, it refers to an area formed in the thin film transistor manufacturing process and surrounded by the buffer layer 120, the gate insulating layer 140, and the first layer 160a of the source electrode 160.

In this case, the first layer 136a of the second contact portion 136 may include a molybdenum-titanium alloy (MoTi), and the second layer 136b may include a low resistance metal. Specifically, the first layer 136a of the second contact portion 136 may be formed of the same material as the first contact portion 135 by the same process, and the second layer 136b of the second contact portion 136 may be formed of the same material as the second layers 150b, 160b, and 170b of the gate electrode 150, the source electrode 160, and the drain electrode 170 by the same process.

According to an embodiment of the present disclosure, the first layer 136a of the second contact portion 136 may be in contact with the first layer 160a of the source electrode 160. In FIG. 3, a structure in which the first layer 136a of the second contact portion 136 is in contact with the first layer 160a of the source electrode 160 is illustrated. In this case, the first contact portion 135 may be in contact with the first layers 160a and 170a of the source electrode 160 and the drain electrode 170.

Specifically, the first contact portion 135 is in contact with the first layers 160a and 170a of the source electrode 160 and the drain electrode 170 in the hole region. In this case, the hole region means a region formed by etching the gate insulating layer 140. More specifically, the first contact portion 135 is formed along the side surface of the gate insulating layer 140, and the first contact portion 135 formed along the side surface may be in contact with the first layers 160a and 170a of the source electrode 160 and the drain electrode 170.

However, an embodiment of the present disclosure is not limited thereto, and the first layer 136a of the second contact portion 136 may be spaced apart from the first layer 160a of the source electrode 160. For example, in FIGS. 4 and 5, there is a difference in a separation distance between the first layer 136a of the second contact portion 136 and the first layer 160a of the source electrode 160, but a structure in which the first layer 136a of the second contact portion 136 is spaced apart from the first layer 160a of the source electrode 160 is illustrated. Also, although not illustrated in the drawing, at least a portion of the first layer 136a of the second contact portion 136 may be in contact with any one of the first layer 160a of the source electrode 160 and the first layer 170a of the drain electrode 170, and the first contact portion 135 may be in contact with the first layer 160a of the source electrode 160 and the first layer 170a of the drain electrode 170.

FIG. 6 is a diagram showing a mechanism for reflection of external light.

FIG. 6 illustrates a mechanism by which the external light 1 and the external light 2 are reflected from the first layer 160a and the second layer 160b of the source electrode 160.

Specifically, the external light 1 of FIG. 6 shows a state in which light incident from the outside is reflected from the first layer 160a of the source electrode 160, and the intensity of the reflected light is weaker than that of the incident light. Accordingly, an increase in reflectance due to external light in the display apparatus may be reduced or prevented.

External light 2 of FIG. 6 shows a state in which light incident from the outside passes through the first layer 160a of the source electrode 160 and is reflected from the surface of the second layer 160b disposed on the first layer 160a. Even in this case, the intensity of the reflected light is weaker than that of the incident light. Accordingly, an increase in reflectance due to external light in the display apparatus may be reduced or prevented.

In this case, although not shown in the drawing, the light reflected from the first layer 160a and the second layer 160b have opposite phases to each other, and thus meet on the surface of the first layer 160a to cause destructive interference. As a result, an increase in reflectance due to external light in the display apparatus may be reduced or prevented, thereby realizing low reflection characteristics.

Although FIG. 6 shows only a state in which the external light is reflected only in the source electrode 160, the external light is reflected not only in the source electrode 160, but also in the first layers 111a, 150a, and 170a and the second layers 111b, 150b, and 170b of the light blocking layer 111, the gate electrode 150, and the drain electrode 170, thereby reducing or preventing an increase in reflectance to implement low reflection characteristics.

Hereinafter, a method of manufacturing a thin film transistor according to an embodiment of the present disclosure will be described.

According to an embodiment of the present disclosure, a method of manufacturing a thin film transistor may include forming the active layer 130 on the base substrate 110, forming the low-reflection material layer 105 on the active layer 130, forming the first metal material layer 107a on the low-reflection material layer 105, and forming the gate electrode 150, the source electrode 160, and the drain electrode 170 by etching the low-reflection material layer 105 and the first metal material layer 107a.

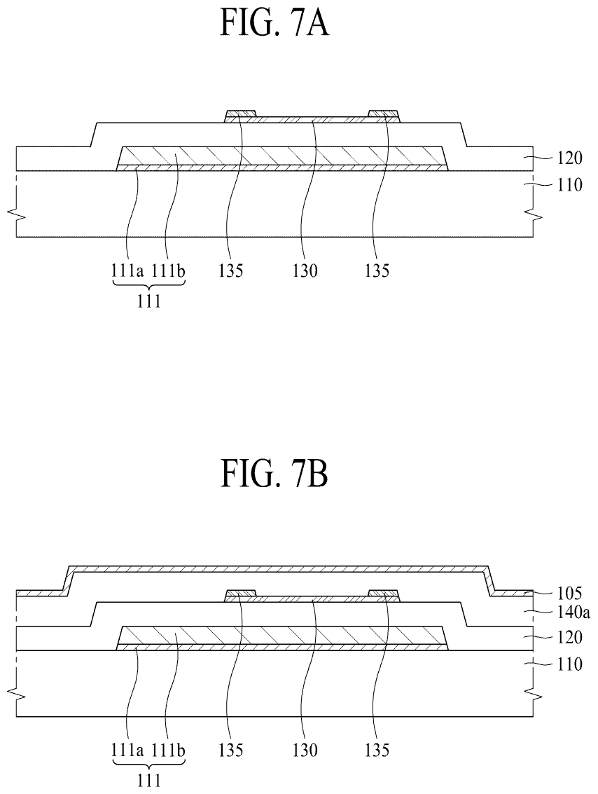

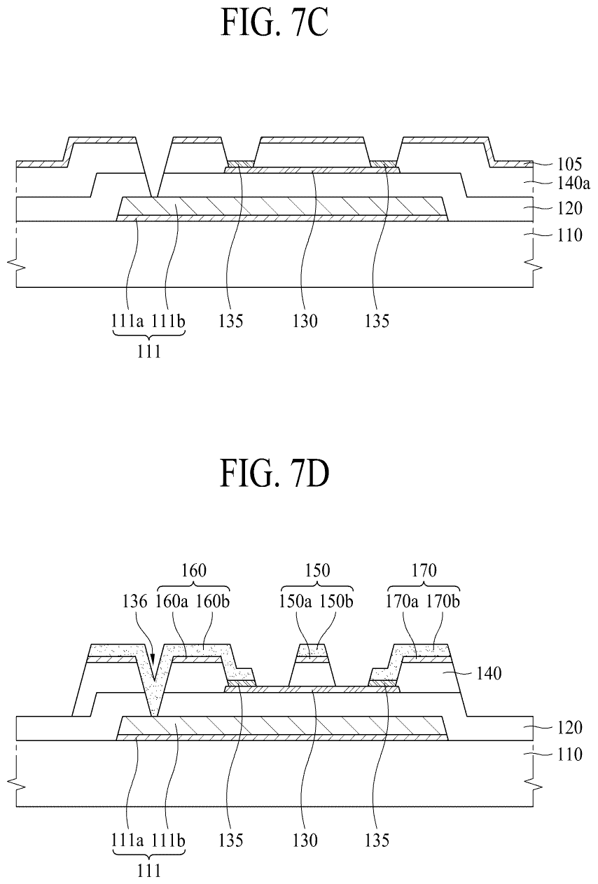

FIGS. 7A to 7D are process diagrams of a method of manufacturing a thin film transistor according to an embodiment of the present disclosure. FIGS. 7A to 7D correspond to the cross-sectional view of FIG. 2.

Referring to FIG. 7A, the light blocking layer 111, the buffer layer 120, and the active layer 130 are sequentially stacked on the base substrate 110, and then the first contact portion 135 is formed on the active layer 130.

In this case, the step of forming the first contact portion 135 on the active layer 130 in FIG. 7a may be performed by patterning using a halftone mask after sequentially forming the oxide semiconductor material layer and the second metal material layer 107b, although not specifically shown in the drawing.

Referring to FIG. 7B, a gate insulating material layer 140a and a low-reflective material layer 105 are sequentially formed on the active layer 130 and the first contact portion 135.

Referring to FIG. 7C, a hole is formed by etching a portion of the gate insulating material layer 140a and the low-reflective material layer 105.

Referring to FIG. 7D, after the first metal material layer 107a is formed on the low-reflection material layer 105, the low-reflection material layer 105 and the first metal material layer 107a are etched to form a gate electrode 150, a source electrode 160, and a drain electrode 170.

In this case, the formed gate electrode 150, the source electrode 160, and the drain electrode 170 include first layers 150a, 160a, and 170a and second layers 150b, 160b, and 170b, respectively, the source electrode 160 and the drain electrode 170 are connected to the active layer 130 through the first contact portion 135, the first contact portion 135 contacts the second layer 160b of the source electrode 160 and the second layer 170b of the drain electrode 170, respectively, the first layers 150a, 160a, and 170a include a metal oxide (MOx) containing an element M, and the second layers 150b, 160b, and 170b may include a low resistance metal.

However, an embodiment of the present disclosure is not limited thereto, and the gate wiring (not shown) extending from the gate electrode 150 may also form a layer corresponding to the first layer 150a and the second layer 150b of the gate electrode 150, and the source wiring (not shown) and the drain wiring (not shown) extending from the source electrode 160 and the drain electrode 170 may also form layers corresponding to the first layers 160a and 170a and the second layers 160b and 170b of the source electrode 160 and the drain electrode 170. As a result, an increase in reflectance with respect to external light in the display apparatus may be suppressed.

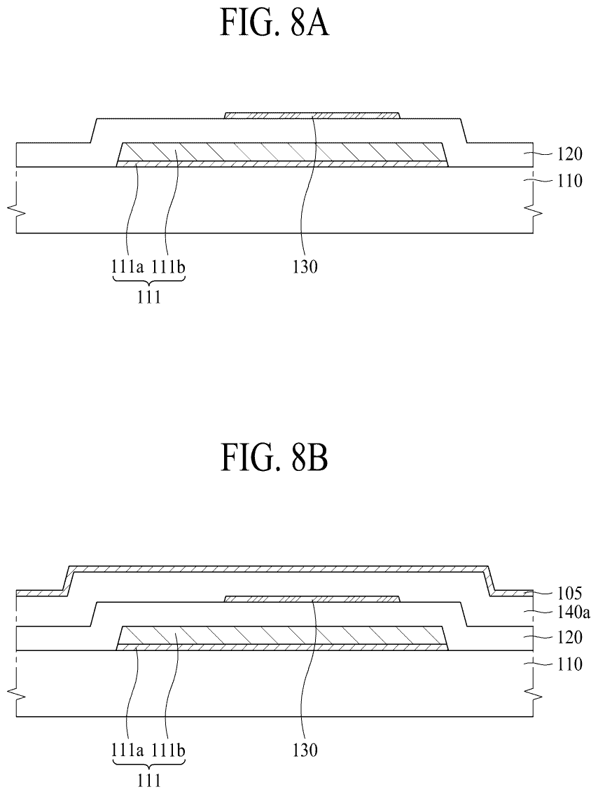

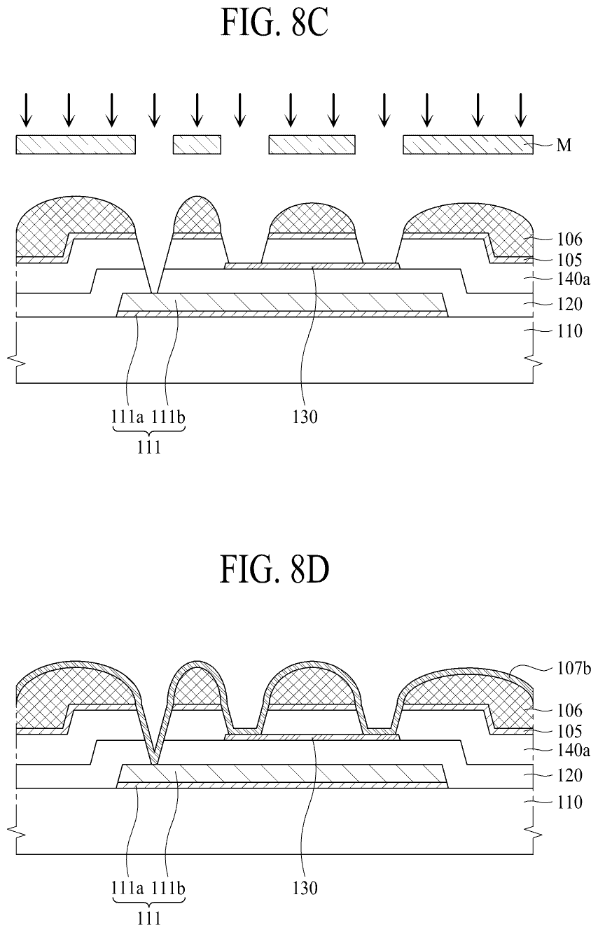

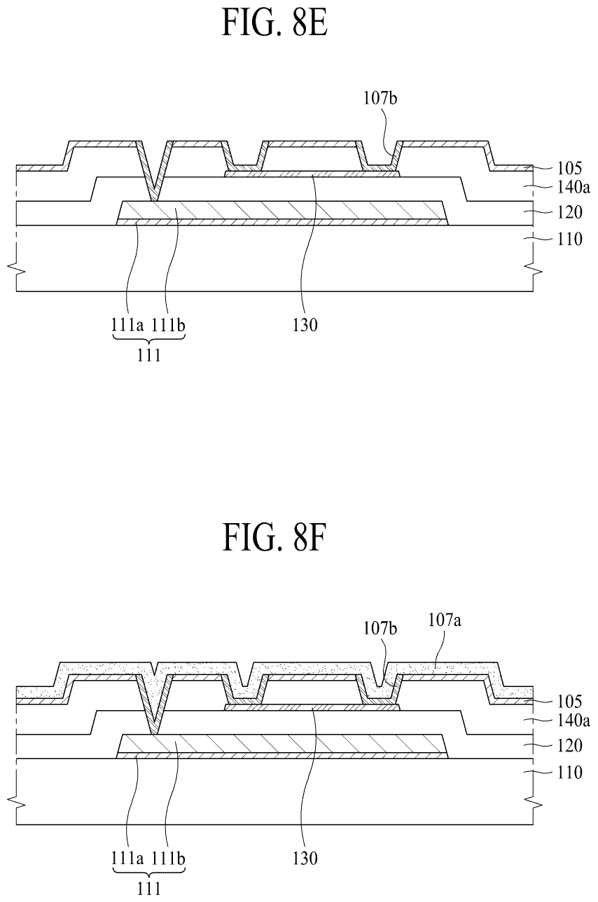

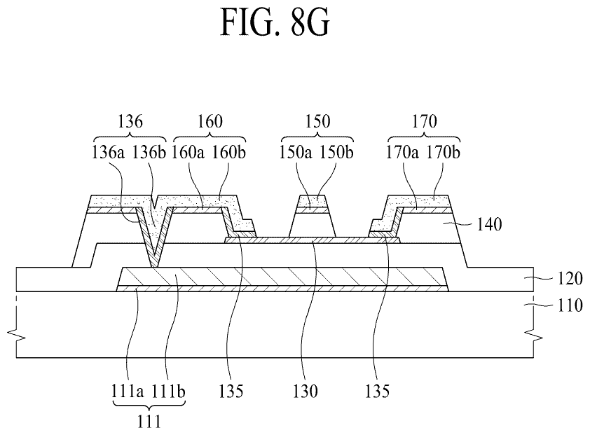

FIGS. 8A to 8G are process diagrams showing a process of manufacturing a thin film transistor according to another embodiment of the present disclosure. FIGS. 8A to 8G correspond to the cross-sectional view of FIG. 2.

Referring to FIG. 8A, a light blocking layer 111, a buffer layer 120, and an active layer 130 are sequentially stacked on the base substrate 110.

Referring to FIG. 8B, a gate insulating material layer 140a and a low-reflective material layer 105 are sequentially formed on the active layer 130.

Referring to FIG. 8C, after the first photoresist material layer 106 is formed on the low-reflective material layer 105, the gate insulating material layer 140a and a part of the low-reflective material layer 105 are etched using the mask M.

Referring to FIG. 8D, a second metal material layer 107b is formed on the first photoresist material layer 106. In this case, the second metal material layer 107b is stacked on the entire surface of the thin film transistor.

Referring to FIG. 8E, the first photoresist material layer 106 and the second metal material layer 107b formed on the first photoresist material layer 106 are removed. In this case, the first photoresist material layer 106 and the second metal material layer 107b formed on the first photoresist material layer 106 are removed. Also, the second contact portion 136 may be formed by the process shown in FIG. 8E.

Referring to FIG. 8F, a first metal material layer 107a may be formed on the low-reflection material layer 105. Specifically, the first metal material layer 107a covers the entire surfaces of the low-reflection material layer 105 and the second metal material layer 107b.

Referring to FIG. 8G, a gate electrode 150, a source electrode 160, and a drain electrode 170 are formed by etching the low-reflective material layer 105 and the first metal material layer 107a. The first contact portion 135 is formed by the etching of FIG. 8G.

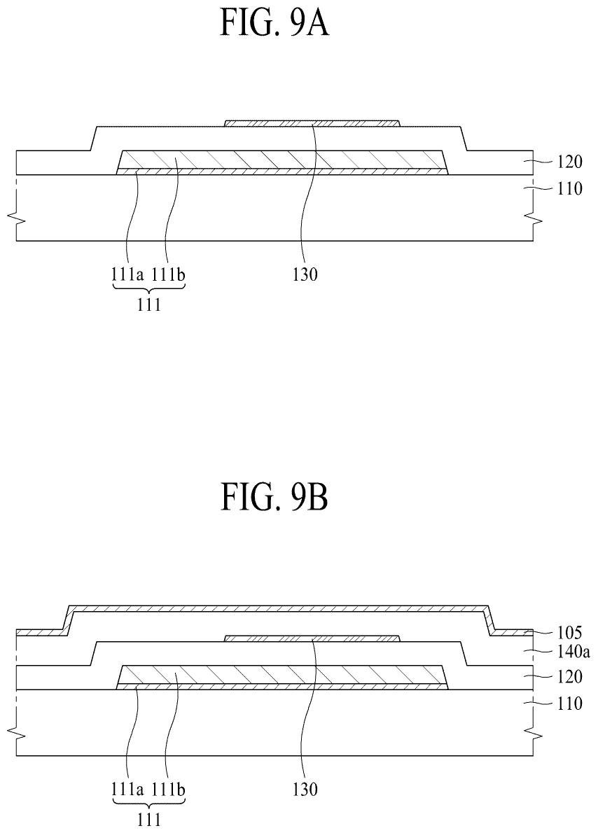

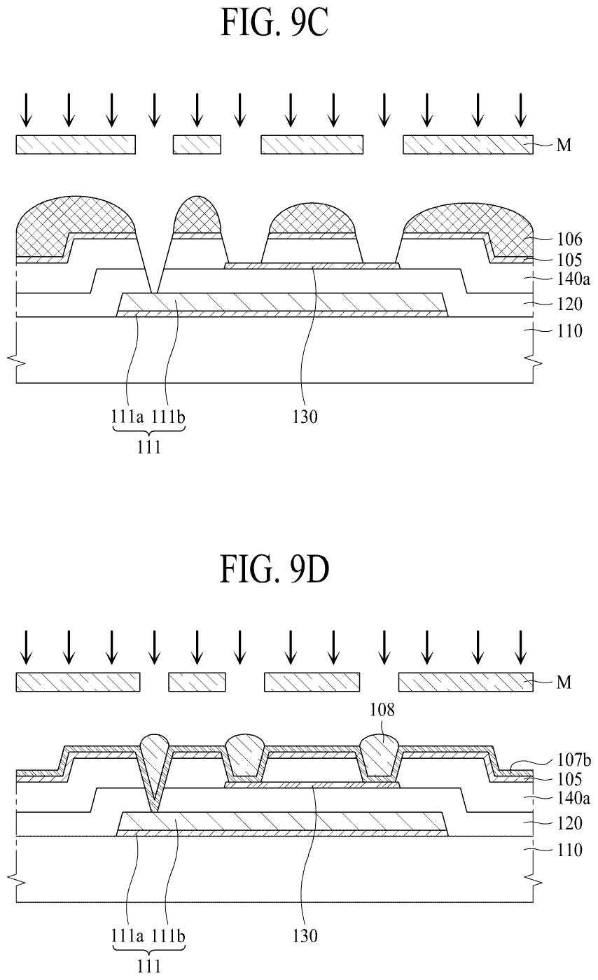

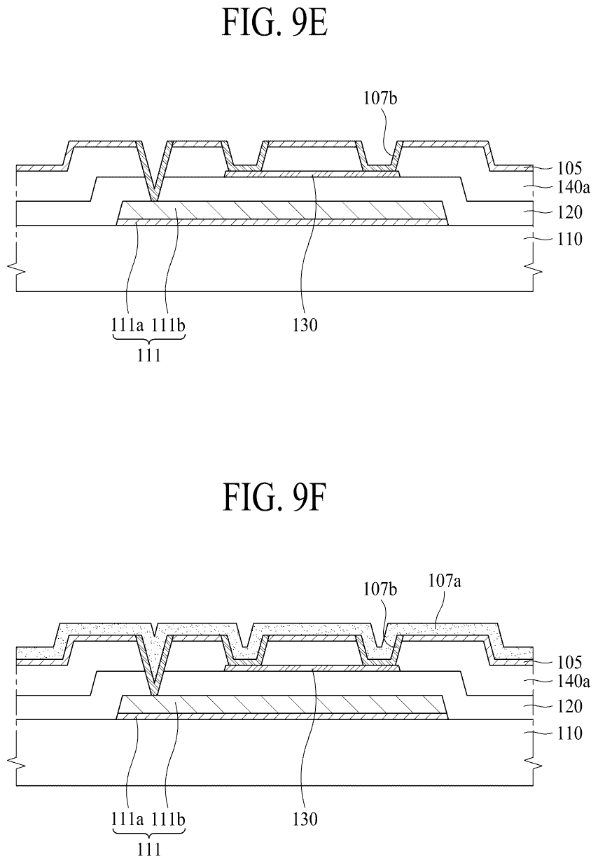

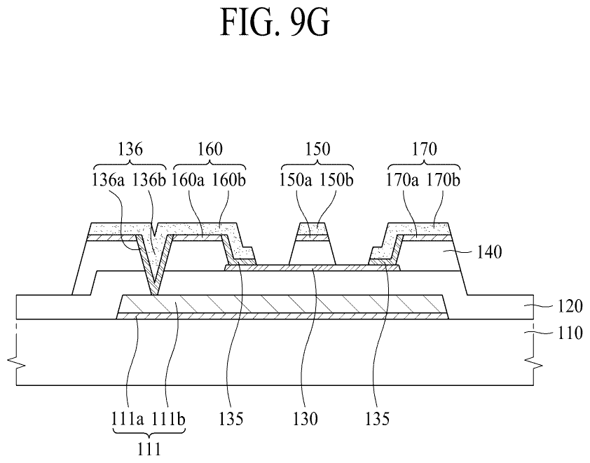

FIGS. 9A to 9G are process diagrams showing a process of manufacturing a thin film transistor according to another embodiment of the present disclosure. FIGS. 9A to 9G correspond to the cross-sectional view of FIG. 2.

Referring to FIG. 9A, a light blocking layer 111, a buffer layer 120, and an active layer 130 are sequentially stacked on the base substrate 110.

Referring to FIG. 9B, a gate insulating material layer 140a and a low-reflective material layer 105 are sequentially formed on the active layer 130.

Referring to FIG. 9C, after the first photoresist material layer 106 is formed on the low-reflective material layer 105, a part of the gate insulating material layer 140a and the low-reflective material layer 105 are etched using the mask M.

Referring to FIG. 9D, the first photoresist material layer 106 is removed, the second metal material layer 107b is formed on the low-reflective material layer 105, and the second photoresist material layer 108 is formed in a region that does not overlap the mask M used in FIG. 9C.

In this case, the first photoresist material layer 106 and the second photoresist material layer 108 are formed of different types of photoresist patterns. For example, one of the first photoresist material layer 106 and the second photoresist material layer 108 may be formed of a positive (+) type photoresist pattern, and the other may be formed of a negative (−) type photoresist pattern.

Referring to FIG. 9E, the second photoresist material layer 108 and the second metal material layer 107b on which the second photoresist material layer 108 is not disposed are removed. In this case, the second photoresist material layer 108 and the second metal material layer 107b on which the second photoresist material layer 108 is not disposed are removed. Also, the second contact portion 136 may be formed by the process shown in FIG. 9E.

Referring to FIG. 9F, a first metal material layer 107a may be formed on the low-reflection material layer 105. Specifically, the first metal material layer 107a covers the entire surfaces of the low-reflection material layer 105 and the second metal material layer 107b.

Referring to FIG. 9G, a first metal material layer 107a is formed on the low-reflection material layer 105, and then the low-reflection material layer 105 and the first metal material layer 107a are etched to form a gate electrode 150, a source electrode 160, and a drain electrode 170. The first contact portion 135 is formed by the etching of FIG. 9G.

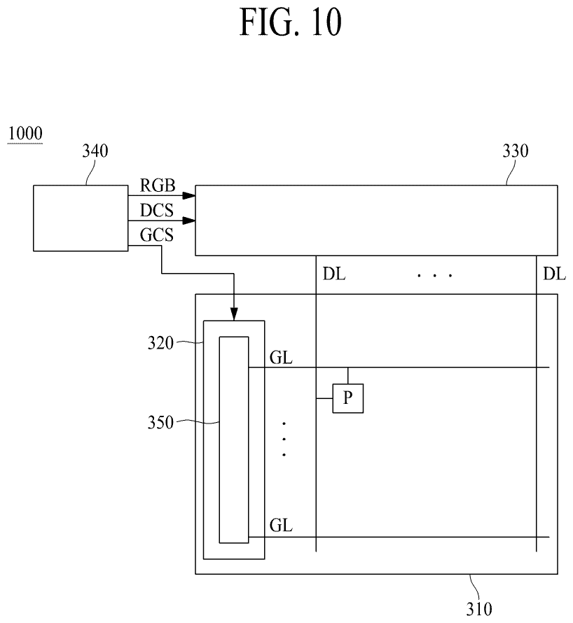

FIG. 10 is a schematic diagram illustrating a display apparatus 1000 according to further still another embodiment of the present disclosure.

As shown in FIG. 10, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the above-described thin film transistors 100, 200, 300, 400, and 500. According to one embodiment of the present disclosure, the gate driver 320 may include the above-described thin film transistors 100, 200, 300, 400, and 500.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistors 100, 200, 300, 400, and 500.

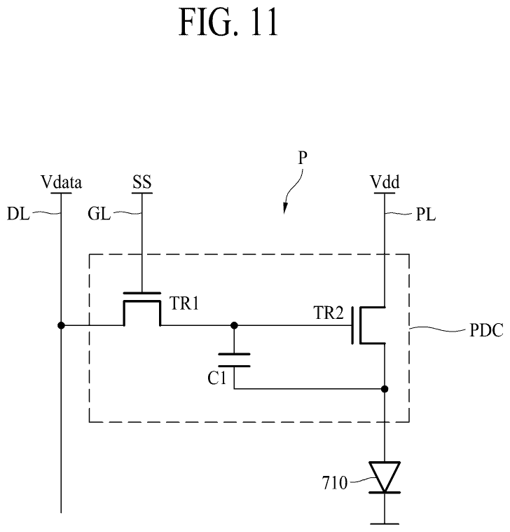

FIG. 11 is a circuit view illustrating any one pixel P of FIG. 10.

The circuit view of FIG. 11 is an equivalent circuit view for the pixel P of the display apparatus 1000 that includes an organic light emitting diode (OLED) as a display element 710.

Referring to FIG. 11, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit PDC of FIG. 11 includes a first thin film transistor TR1 that is a switching transistor and a second thin film transistor TR2 that is a driving transistor. The display apparatus 1000 according to another embodiment of the present disclosure may include at least one of the above-described thin film transistors 100, 200, 300, 400, and 500.

The first thin film transistor TR1 is connected to the gate line GL and the data line DL and is turned on or off by the scan signal SS supplied through the gate line GL. In this case, the gate line GL and the data line DL may form layers corresponding to the first layers 150a, 160a, 170a, and the second layers 150b, 160b, 170b of the gate electrode 150, the source electrode 160, and the drain electrode 170 according to an embodiment of the present disclosure. As a result, an increase in reflectance with respect to external light in the display device may be suppressed.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

According to the present disclosure, the following advantageous effects may be obtained.

In the thin film transistor according to an embodiment of the present disclosure, since the source electrode and the drain electrode have a double layer structure having low reflection characteristics, an increase in reflectance may be suppressed or prevented.

The thin film transistor according to an embodiment of the present disclosure may suppress or prevent an increase in reflectance by adjusting a double layer structure having low reflection characteristics of a source electrode and a drain electrode, and may have characteristics of a low resistance wiring.

In addition to the above-mentioned effects, other features and advantages of the present disclosure may be described below, or may be clearly understood by those of ordinary skill in the art to which the present disclosure belongs from such techniques and descriptions.

In addition to the above-mentioned effects, other features and advantages of the present disclosure will be described below or clearly understood by those of ordinary skill in the art to which the present disclosure belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor includes:
a base substrate;
an active layer on the base substrate;
a gate electrode spaced apart from the active layer and overlapping at least part of the active layer;
a source electrode connected to the active layer; and
a drain electrode spaced apart from the source electrode and connected to the active layer;
wherein each of the gate electrode, the source electrode and the drain electrode include a first layer and a second layer on the first layer,
wherein each of the source electrode and the drain electrode is connected to the active layer through a first contact portion,
wherein the first contact portion contacts each of the second layer of the source electrode and the second layer of the drain electrode,
wherein the first layer includes a metal oxide containing an element M,
wherein the second layer includes a low resistance metal, and
wherein the element M includes a group 6B element.

2. The thin film transistor of claim 1, wherein the group 6B element includes at least one of chromium, molybdenum, and tungsten, and
wherein the low resistance metal includes at least one of Cu, Ag, Al, Mo, and Ti.

3. The thin film transistor of claim 1, wherein the first layer further includes a dopant, and
wherein the dopant includes at least one of Ta, Ti, and Zn.

4. The thin film transistor of claim 1, wherein the first layer of the source electrode, the first layer of the drain electrode, and the first layer of the gate electrode are formed on the same layer.

5. The thin film transistor of claim 1, wherein the gate electrode, the source electrode, and the drain electrode are formed on the same layer.

6. The thin film transistor of claim 1, wherein the active layer includes:
a channel area overlapping the gate electrode;
a source area connected to one side of the channel area; and
a drain area connected to the other side of the channel area; and
wherein the first contact portion is disposed on the source area and the drain area.

7. The thin film transistor of claim 1, wherein the first contact portion includes at least one selected from metal and transparent conductive oxide.

8. The thin film transistor of claim 7, wherein the metal includes a molybdenum-titanium alloy.

9. The thin film transistor of claim 1, wherein each of the first layer of the source electrode, the first layer of the drain electrode, and the first layer of the gate electrode have a thickness of 200 Å to 600 Å.

10. The thin film transistor of claim 1, further including a light blocking layer on the base substrate, and
wherein the source electrode is connected to the light blocking layer through a second contact portion.

11. The thin film transistor of claim 10, wherein the light blocking layer includes a first layer and a second layer on the first layer,
wherein the first layer includes a metal oxide containing an element M,
wherein the second layer includes a low resistance metal,
wherein the element M includes a group 6B element, and
wherein the low resistance metal includes at least one of Cu, Ag, Al, Mo, and Ti.

12. The thin film transistor of claim 10, wherein the second contact portion includes a low resistance metal, and
wherein the low resistance metal includes at least one of Cu, Ag, Al, Mo, and Ti.

13. The thin film transistor of claim 12, wherein the second contact portion includes:
a first layer in contact with the light blocking layer; and
a second layer on the first layer;
wherein the first layer includes molybdenum-titanium alloy, and
wherein the second layer includes the low resistance metal.

14. The thin film transistor of claim 13, wherein at least a part of the first layer of the second contact portion contacts any one of the first layer of the source electrode and the first layer of the drain electrode, and
wherein the first contact portion contacts the first layer of the source electrode and the first layer of the drain electrode.

15. A thin film transistor includes:
a gate electrode, a source electrode, and a drain electrode;
wherein at least one of the gate electrode, the source electrode and the drain electrode includes a first layer and a second layer on the first layer,
wherein the first layer includes a metal oxide (MOx) containing an element M,
wherein the second layer includes a low resistance metal, and
wherein the element M includes a group 6B element.

16. A display apparatus comprising:
a display panel having a display area and a non-display area adjacent to the display area; and
a plurality of pixels included in the display area, each pixel of the plurality of pixels including a light emitting diode and a thin film transistor electrically connected to the light emitting diode,
wherein the thin film transistor includes:
a base substrate;
an active layer on the base substrate;
a gate electrode spaced apart from the active layer and overlapping at least part of the active layer;
a source electrode connected to the active layer; and
a drain electrode spaced apart from the source electrode and connected to the active layer;
wherein each of the gate electrode, the source electrode and the drain electrode include a first layer and a second layer on the first layer,
wherein each of the source electrode and the drain electrode is connected to the active layer through a first contact portion,
wherein the first contact portion contacts the second layer of the source electrode and the second layer of the drain electrode, respectively,
wherein the first layer includes a metal oxide containing an element M,
wherein the second layer includes a low resistance metal, and
wherein the element includes a group 6B element.

17. A manufacturing method of the thin film transistor comprising:
forming an active layer on the base substrate;
forming a first contact portion on the active layer;
forming a low-reflective material layer on the active layer;
forming a first metal material layer on the low-reflective material layer; and
forming a gate electrode, a source electrode, and a drain electrode by etching the low-reflective material layer and the first metal material layer,
wherein each of the gate electrode, the source electrode, and the drain electrode includes a first layer and a second layer on the first layer,
wherein each of the source electrode and the drain electrode is connected to the active layer through a first contact portion,
wherein the first contact portion contacts each of the second layer of the source electrode and the second layer of the drain electrode,
wherein the first layer includes a metal oxide containing an element M,
wherein the second layer includes a low resistance metal, and
wherein the element M includes a group 6B element.

18. The manufacturing method of the thin film transistor of claim 17, wherein the forming the first contact portion on the active layer is performed by sequentially forming an oxide semiconductor material layer and a second metal material layer, and then patterning using a halftone mask.

19. The manufacturing method of the thin film transistor of claim 17, wherein the forming the first contact portion on the active layer is performed after the forming a low-reflective material layer on the active layer,
further includes:
forming a first photoresist material layer on the low-reflective material layer to etch part of it;
forming a second metal material layer on the first photoresist material layer; and
removing the first photoresist material layer and the second metal material layer formed on the first photoresist material layer.

20. The manufacturing method of the thin film transistor of claim 17, wherein the forming the first contact portion on the active layer is performed after forming a low-reflective material layer on the active layer,
further includes:
forming a first photoresist material layer on the low-reflective material layer, and etching using a mask;
removing the first photoresist material layer;
forming a second metal material layer on the low-reflective material layer;
forming a second photoresist material layer on the second metal material layer; and
removing the second metal material layer that does not overlap the second photoresist material layer using the mask.

21. The manufacturing method of the thin film transistor of claim 20, one of the first photoresist material layer and the second photoresist material layer is formed of a positive type photoresist pattern, and the other is formed of a negative type photoresist pattern.
